(19) United States
(12) Patent Application Publication
(10) Pub. No.: US 2007/0236887 A1
(43) Pub. Date: Oct. 11, 2007

(54) Heatsink module of heat-generating electronic elements on circuit board

(75) Inventors: Yi-Lun Cheng, Taipei (TW); Chun-Lung Lin, Taipei (TW); Frank Wang, Taipei (TW)

Correspondence Address: BIRCH STEWART KOLASCH & BIRCH, PO BOX 747, FALLS CHURCH, VA, 22040-0747, US

(73) Assignee: INVENTEC CORPORATION

(21) Appl. No.: 11/400,314

(22) Filed: Apr. 10, 2006

(51) Int. Cl. H05K 7/20

(52) U.S. Cl. 361/700

(57) ABSTRACT

A heatsink module of heat-generating electronic elements on a circuit board is provided. The heatsink module is used to conduct and dissipate the heat generated by heat-generating electronic elements. The heatsink module includes a heat-conducting substrate contacting the heat-generating electronic elements. The heat-conducting substrate is locked on the heat-generating electronic element by a spring fastening. With die elastic force, the spring fastening can continuously press the heat-conducting substrate, such that the heat is conducted from the heat-generating electronic element to the heat-conducting substrate efficiently. Also, a heat pipe is disposed in the heat-conducting substrate, thus shortening the path between the heat pipe and the heat-generating electronic element for conducting heat, and increasing the contact area and improving the heat dissipation.

### BACKGROUND OF THE INVENTION

1. Field of Invention

The present invention relates to a design of a heatsink module, and more particularly, to a heatsink module applied in heat-generating electronic elements.

2. Related Art

Electronic elements in the computer equipment, such as Central Processing Unit (CPU) chips and power integrated circuits, produce heat when operating. The more wattage the CPU chip has, the more power it consumes. Additionally, the integrated circuit is highly integrated, such that the heat sources are gathered When operating, a large quantity of heat may be generated. Moreover, the faster the operation is, the more heat it produces. As the operating temperature greatly affects the probability of the computer crash, a good control of temperature can guarantee the computer equipment will have a high reliability and maintain stable operation of the heat-generating electronic elements.

In order to reduce the working temperature of the heat-generating electronic elements and keep an effective operation, various heatsink modules are designed based on a heatsink design. Referring to FIG. 1, generally, a heatsink module employs a design of a combination of a heat-conducting substrate 10a together with a heat pipe 20a and a heatsink tin array 60a to conduct and dissipate heat, thus achieving a heat dissipation effect. The heat from a heat-generating electronic element 30a is conducted to the heat-conducting substrate 10a (which is a metal bulk with a high heat transfer performance) via a package surface, such that the heat can be conducted upwards to the heat pipe 20a by the heat-conducting substrate 10a, and then to the heatsink fin array 60a through the phase transformation of the working fluid in the heat pipe 20a, thereby achieving a good heat dissipation effect.

The heatsink module with the combination of the heat-conducting substrate and the heat pipe and heatsink fin has a characteristic of a sufficiently compacted thickness, particularly adapted to the portable notebook computer in need of light weight, small volume and thin thickness. For the heatsink module manufacturer, in addition to a highly efficient heat dissipation effect for facilitating dissipating intense heat of the heat-generating electronic element, manufacturing efficiency and manufacturing cost of the heatsink module should be taken into consideration, to enhance the competitive edge of the product.

In the above conventional technology, a die-cast molding is mostly used in the manufacture of heat-conducting substrate, which is cost-consuming and heavy. Therefore, an aluminum element contacting the CPU for dissipating heat is formed by a metal sheet stamping instead of die-casting The substitute heat-conducting substrate 10a is light, but the strength is weak. To avoid a bending deformation of the heat-conducting substrate 10a after being locked, an extra auxiliary block 11a is added to strengthen the structure. However, adding the auxiliary block 11a on the heat-conducting substrate 10a increases the complexity of the assembly process of the heatsink module, resulting in an inconvenience, and also increasing the cost of both labor and material (as shown in FIG. 1).

As the structure of tie metal sheet is not rigid and thick enough, it is easily forced into a bending deformation in the actual assembling. In the process of locking the heat-conducting substrate and the CPU on the circuit board by screws, when the locking point is pressed, the effective attachment area of the center of the heat-conducting substrate and the CPU may be reduced due to being applied with an uneven forced mechanism. Also the heat-conducting substrate or the CPU may be cracked, thus significantly reducing the heat dissipation effect Furthermore, it consumes a lot of time locking by screws.

In the aspect of heat dissipation, the heat pipe is stacked on the heat-conducting substrate, and thus there is still a long pitch between the heat pipe and the heat-generating electronic element, such that the path for conducting heat from the heat-generating electronic element to the heat pipe is long. Furthermore, in the stack attachment, the contact area between the heat pipe and the heat-conducting substrate is still insufficient, affecting the heat dissipation.

### SUMMARY OF THE INTENTION

In the conventional technology disclosed above, the factors as follows are not fully taken into consideration, including the uneven forced mechanism between the heat-conducting substrate and the heat-generating electronic element, the reduced dissipation area between the heat-conducting substrate and the heat-generating electronic element, and the insufficient effective contact area between the heat-conducting substrate and the heat pipe, and the long heat-conducting path between the heat-generating electronic element and the heat pipe affecting the dissipation efficiency. Therefore, the present invention provides a design of heatsink module for heat-generating electronic elements.

A heatsink module disclosed in the present invention is disposed on the heat-generating electronic element, including a heat-conducting substrate, a heat pipe, and a spring fastening. The bottom surface of the heat-conducting substrate contacts the heat-generating electronic element, and the top surface thereof has a groove for contacting and accommodating the heat pipe. A fastening portion set in the spring fastening catches a hook portion of a hook stud, such that a pressing portion of the spring fastening is pressed against the heat-conducting substrate. And then a locking portion set in a spring fastening is bound with a screw stud through a screwing element, such that the heat-conducting substrate is locked on a circuit board, thereby fully attaching the opposite surfaces of the heat-conducting substrates and the heat-generating electronic element together. The heat produced by the heat-generating electronic clement is conducted to the heat pipe by the heat-conducting substrate, and then to a heatsink fin array having a plurality of heatsink fins by the capillary structure and working fluid of the heat pipe for being discharged outside.

The heat pipe is accommodated in the groove opened in the heat-conducting substrate, thus increasing the effective contact area, shortening the path between the heat pipe and the heat-generating electronic element for conducting heat, raising the heat dissipation efficiency, and simplifying the assembly process without reducing the ability of resisting the bending-deformation of the heat-conducting substrate and saving a conventional auxiliary block used for strengthening structure on the heat-conducting substrate. The spring fastening is set with a pressing portion, a fastening portion, and a locking portion to lock the heat-conducting substrate on the circuit board, thereby reducing the unevenness of the forced mechanism of locking the heat-conducting substrate by screws, increasing the efficiency in resisting the bending deformation, providing a downward pressing force to attach the heat-conducting substrate closely with the heat-generating electronic element, and also saving time spent locking screws and manufacturing cost.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and thus are not limitative of the present invention, and wherein:

FIG. 1 is an assembly view of a conventional heatsink module;

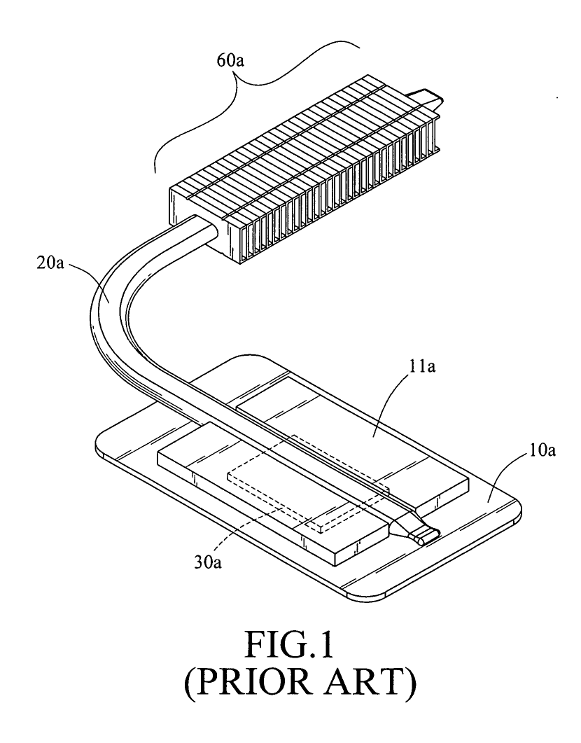

FIG. 2 is an exploded view of a structure of a first embodiment;

FIG. 3 is an assembly view of the structure of the first embodiment;

FIG. 4 is an outside view of the assembly of the first embodiment;

FIG. 5 is a sectional view of the first embodiment; and

FIG. 6 is an outside view of an assembly of a second embodiment.

### DETAILED DESCRIPTION OF THE INVENTION

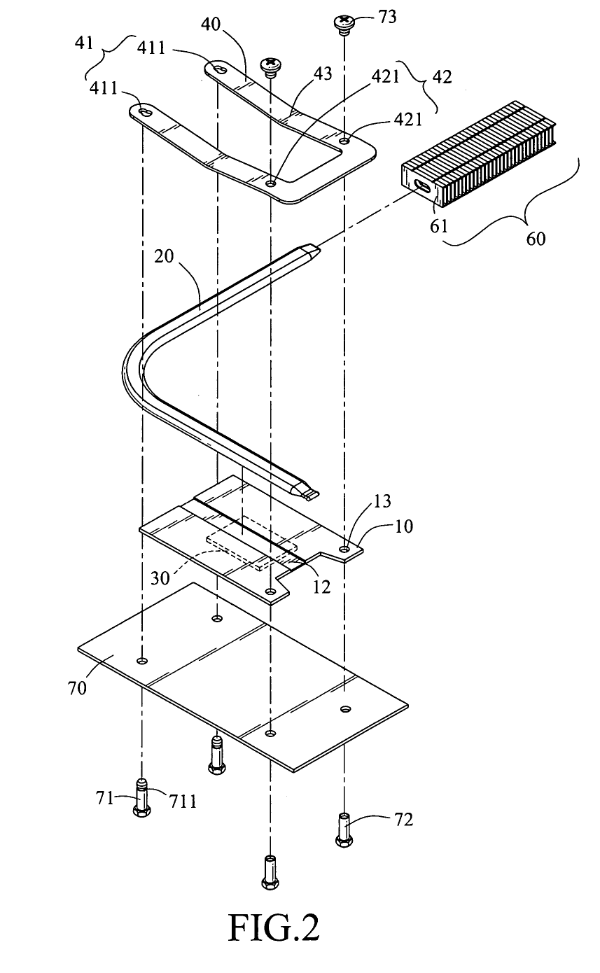

A heatsink module disclosed in the present invention refers to a heatsink module adapted to a Central Processing Unit (CPU) chip for performing computation but is not limited to the CPU chip. For example, an integrated circuit chip producing heat can also employ the technology disclosed in the present invention. In the following detailed description of the present invention, the CPU chip is illustrated as a most preferred embodiment of the present invention A first embodiment of the present invention is shown in FIG. 2. The bottom surface of a heat-conducting substrate 10 contacts a CPU chip 30, and the top surface thereof is provided with a groove 12 for accommodating one end of a heat pipe 20, the other end of which is connected to a heatsink fin array 60 having a plurality of heatsink fins 61. In order to lock the heat-conducting substrate 10 by the spring fastening 40, a fastening portion 41 and a locking portion 42 of the spring fastening 40 should be aligned with a hook stud 71 and a screw stud 72 on the circuit board 70, such that two fastening holes 411 in the fastening portion 41 are caught by the hook portions 711 of the hook stud 71. A pressing portion 43 is pressed against the heat-conducting substrate 10, such that two screw holes 421 in the locking portion 42 are aligned with two perforations 13 opened in the heat-conducting substrate 10, in which the two perforations 13 of the heat-conducting substrate 10 and the two screw holes 421 of the spring fastening 40 are provided to allow the screw stud 72 to pass through, and thus the screwing element 73 may be locked with the screw stud 72.

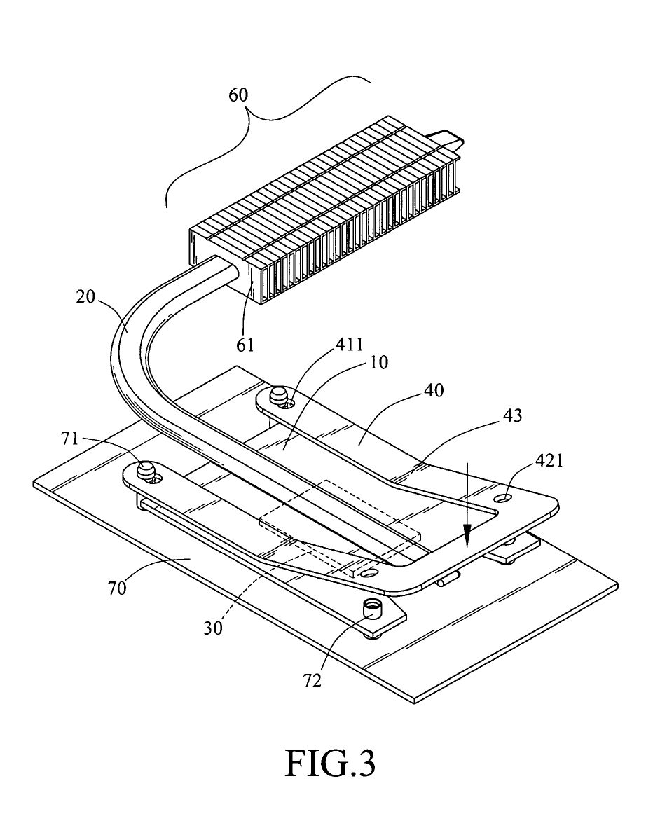

Referring to FIG. 3, when two fastening holes 411 in the spring fastening 40 are buckled with the hook studs 71, the fastening portion 41 is attached to the heat-conducting substrate 10 (as shown in FIG. 2), and the pressing portion 43 is pressed against the heat-conducting substrate 10, with an angle formed between the locking portion 42 and the heat-conducting substrate 10, such that the screw studs 72 can pass through the two screw holes 421 in the spring fastening 40. Thus, the locking portion 42 is attached with the heat-conducting substrate 10 (as shown in FIG. 2), and the spring fastening 40 may provide a sufficient downward pressing force to the, heat-conducting substrate 10.

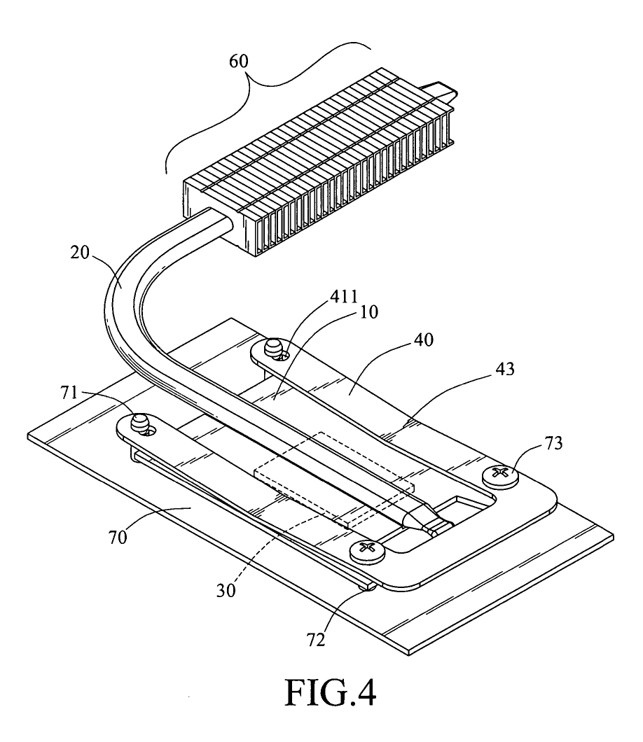

Referring to FIG. 4, the top surface of the heat-conducting substrate 10 contacts one end of the heat pipe 20, and the bottom surface of the heat-conducting substrate 10 contacts a CPU chip 30. A spring fastening 40 is disposed on the heat-conducting substrate 10 for fixing the heat-conducting substrate 10, while the other end of the heat pipe 20 is connected to a heatsink fin array 60. Furthermore, the heat-conducting substrate 10 is fixed by the fastening hole 411 buckled with the hook stud 71 on the circuit board 70, and the locking between the screw stud 72 and the screwing clement 73.

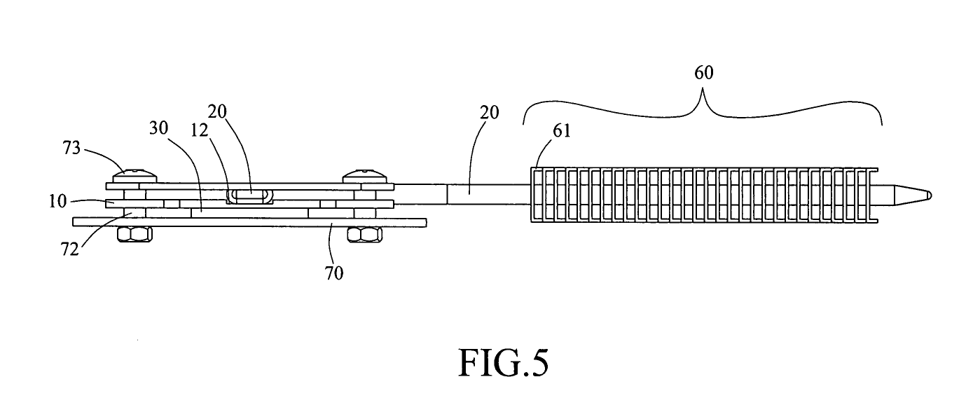

Referring to FIG. 5, the heat produced by the heat-generating electronic element 30 can be conducted to the heat-conducting substrate 10, and then to the heat pipe 20 in the groove 12 by the heat-conducting substrate 10. After that the heat is then conducted to heatsink fin array 60 having a plurality of heatsink fins 61 by a capillary structure and working fluid of the heat pipe 20 for being discharged outside.

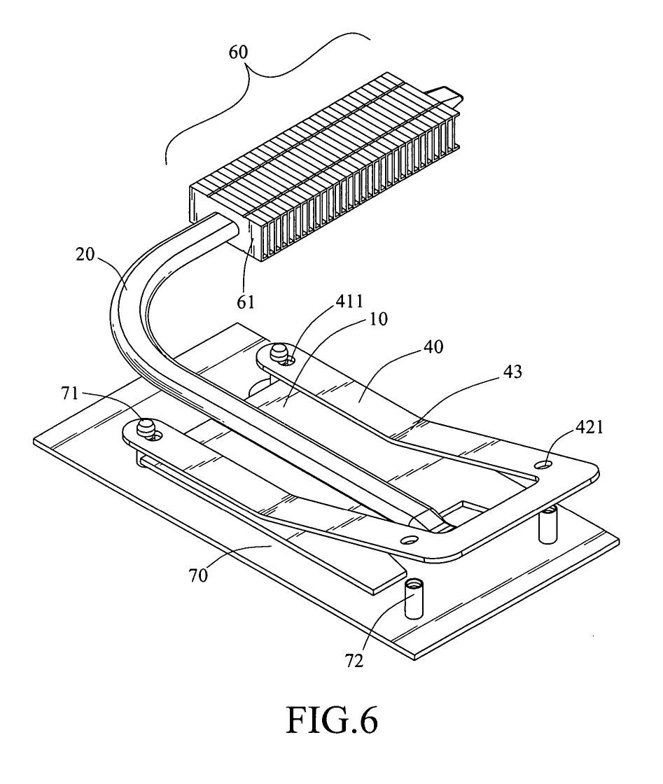

The second embodiment of the present invention is shown in FIG. 6. When the two fastening holes 411 on the spring fastening 40 are buckled with the hook stud 71, the fastening portion 41 is attached with the heat-conducting substrate 10. And the pressing portion 43 is also pressed against the heat-conducting substrate 10, such that an angle is formed between the locking portion 42 and the heat-conducting substrate 10. As there is no perforation in the heat-conducting substrate 10, the screw studs 72 directly pass through the two screw holes 421 of the spring fastening 40, thereby the locking portion 42 is attached with the heat-conducting substrate 10, and the spring fastening 40 can provide a sufficient downward pressing force to the heat-conducting substrate 10.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A heatsink module of heat-generating electronic elements on a circuit board, for conducting and dissipating heat of the heat-generating electronic elements, the heatsink module comprising:
a heat-conducting substrate, having a groove, and contacting a top surface of the heat-generating electronic element for receiving the heat generated by the heat-generating electronic element;
a heat pipe, with one end contacted to the groove and disposed therein, for introducing the heat source received by the heat-conducting substrate, and the other end located in a heatsink area;
a hook stud with a hook portion, wherein the hook stud is disposed at one side of the heat-generating electronic element;
a screw stud, disposed at another side of the heat-generating electronic element; and
a spring fastening with a fastening portion, a locking portion and a pressing portion, wherein the pressing portion is positioned between the fastening portion and the locking portion, and combined with the fastening portion by the hook stud, such that the pressing portion is attached with the heat-conducting substrate, and the screw stud is combined with the locking portion by a screwing element.

2. The heatsink module as claimed in claim 1, wherein the material for the heat-conducting substrate is copper.

3. The heatsink module as claimed in claim 1, wherein the material of the heat-conducting substrate is aluminum.

4. The heatsink module as claimed in claim 1, wherein the material for the heat-conducting substrate is copper-aluminum alloy.

5. The heatsink module as claimed in claim 1, wherein the heat-generating electronic element is a Central Processing Unit (CPU) chip.

6. The heatsink module as claimed in claim 1, wherein the heat-generating electronic element is a display chip.

7. The heatsink module as claimed in claim 1, wherein the heat-generating electronic element is a Northbridge Chip.

8. The heatsink module as claimed in claim 1, wherein the heat-generating electronic element is a Southbridge Chip.

9. The heatsink module as claimed in claim 1, wherein the circuit board is a motherboard.

10. The heatsink module as claimed in claim 1, wherein the screwing element is a screw.

11. The heatsink module as claimed in claim 1, wherein the fastening portion comprises a plurality of fastening holes.

12. The heatsink module as claimed in claim 1, wherein the locking portion comprises a plurality of screw holes.

13. The heatsink module as claimed in claim 1, wherein the pressing portion contacts the heat-conducting substrate.

14. The heatsink module as claimed in claim 1, wherein an angle is formed between the spring fastening and the heat-conducting substrate.
